(19) United States
(12) Patent Application Publication
(10) Pub. No.: US 2007/0272956 A1
(43) Pub. Date: Nov. 29, 2007

(54) Nonvolatile semiconductor memory

(75) Inventors: Ikuo Kurachi, Tokyo (JP); Toshiyuki Orita, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/785,645

(22) Filed: Apr. 19, 2007

(30) Foreign Application Priority Data
May 23, 2006 (JP) 2006-142476

(51) Int. Cl. H01L 29/76

(52) U.S. Cl. 257/288; 257/E29.226

(57) ABSTRACT

A control electrode is provided via an insulating film on one main surface of a semiconductor substrate having a first conductivity type. A pair of dopant diffusion regions are formed, with the control electrode therebetween, in a surface layer region of the semiconductor substrate. Resistance variation sections are formed in the surface layer region of the semiconductor substrate between the control electrode and the dopant diffusion regions. The resistance variation sections are of the second conductivity type and have a dopant concentration lower than that of the dopant diffusion regions. First and second main electrodes are provided on the dopant diffusion regions of the semiconductor substrate. A first charge storage section is provided between the first main electrode and control electrode on the semiconductor substrate. A second charge storage section is provided between the second main electrode and control electrode on the semiconductor substrate.

### BACKGROUND OF THE INVENTION

1. Field of the Invention

The present invention relates to a nonvolatile semiconductor memory, a method for recording information in the nonvolatile semiconductor memory, and a method for manufacturing the nonvolatile semiconductor memory.

2. Description of the Related Art

A conventional nonvolatile semiconductor memory will be described below with reference to FIG. 7 of the accompanying drawings. FIG. 7 is a schematic cross-sectional view of a nonvolatile semiconductor memory. A base cell (referred to hereinbelow as a memory cell) 210 of the nonvolatile semiconductor memory includes a MOS-type transistor (MOSFET) having a gate oxide film 232 and a gate electrode 234 on a silicon substrate 220 and two charge storage sections, that is, first and second charge storage sections 240a and 240b in positions sandwiching the gate electrode 234. The first and second charge storage sections 240a and 240b have a laminated structure capable of storing electric charges (referred to hereinbelow as an ONO laminated insulating film). First silicon oxide films 241a and 241b, silicon nitride films 242a and 242b, and second silicon oxide films 243a and 243b are laminated successively in the laminated structures.

In the memory cell 210, first and second resistance variation sections 222a and 222b are provided in the surface layer region of the silicon substrate 220 that are located below the first and second charge storage sections 240a and 240b. The electric resistance of the first and second resistance variation sections 222a and 222b varies depending on whether electrons have been accumulated in the first and second charge storage sections 240a and 240b, and “1” and “0” data are differentiated depending on whether electrons have been accumulated in the first and second charge storage sections 240a and 240b. For example, when electrons have been accumulated in the first charge storage section 240a, the resistance of the first resistance variation section 222a located below the first charge storage section 240a increases. At this time, if a first main electrode region (for example, a drain) 224a is at a ground potential and a second main electrode region (for example, a source) 224b is at a positive potential, a drain current decreases due to the increase in the resistance of the first resistance variation section 222a. On the other hand, when no electrons are accumulated in the first charge storage section 240a, the resistance of the first resistance variation section 222a does not increase and, therefore, the drain current does not decrease.

When the resistance of the second resistance variation section 222b located below the second charge storage section 240b changes depending on the presence or absence of the charge stored in the second charge storage section 240b, the drain current is not influenced because the depleted layer is formed in the vicinity of the second main electrode region (source) 224b.

If a voltage applied to the drain 224a and a voltage applied to the source 224b are switched, it is possible to determine whether or not the electrons are accumulated in the second charge storage section 240b. Thus, 2-bit data can be stored in one memory cell. Such nonvolatile semiconductor memory is disclosed in, for example, Japanese Patent Applications Kokai (Laid-open) No. 2004-56089, No. 2004-349304 and No. 2005-64295.

### SUMMARY OF THE INVENTION

In the above-described conventional nonvolatile semiconductor memory, information is written by injecting hot electrons generated in the resistance variation section into the charge storage section with an electric field (as indicated by the arrows IV in FIG. 7) between the gate electrode and silicon substrate surface. Because the effective film thickness of the charge storage section from the silicon substrate surface to the gate electrode is large, the electric field does not become large. As a result, the injection efficiency of hot electrons is not high and the write time is long. Since the write time is long, the electric current consumed during writing is long.

If a voltage applied to the gate electrode or drain electrode is raised to increase the injection efficiency of hot electrons, other memory cells formed in the same silicon substrate will be affected by this voltage, and will cause unnecessary injection of hot electrons.

The comprehensive research were conducted by the inventors in order to increase the write efficiency. The inventors formed a polysilicon electrode, which served as a drain electrode or source electrode, adjacent to a charge storage section. The inventors placed the charge storage section between the drain electrode or source electrode and the gate electrode. The inventors found that the drain electrode or source electrode functioned to cause the hot electrons generated in the resistance variation section to inject into the charge storage section. The inventors found that this can increase the write efficiency.

One object of the present invention is to provide a nonvolatile semiconductor memory that can increase the charge injection efficiency and enable the writing at a small current and a low voltage.

Another object of the present invention is to provide a method for writing information in such nonvolatile semiconductor memory.

Still another object of the present invention is to provide a method for manufacturing such nonvolatile semiconductor memory.

According to one aspect of the present invention, there is provided a nonvolatile semiconductor memory that includes a semiconductor substrate, a control electrode, and first and second dopant diffusion regions. The nonvolatile semiconductor memory also includes a first resistance variation section, a second resistance variation section, a first main electrode, a second main electrode, a first charge storage section, and a second charge storage section.

The control electrode is provided via an insulating film on one main surface of the semiconductor substrate. The semiconductor substrate has a first conductivity type. The first and second dopant diffusion regions are formed in the surface layer region on the main surface side of the semiconductor substrate and sandwich the control electrode. These dopant diffusion regions have a second conductivity type that is different from the first conductivity type. The first resistance variation region extends from a lower face of the control electrode to the first dopant diffusion region in the surface layer region of the substrate. The second resistance variation region extends from the lower face of the control electrode to the second dopant diffusion region in the surface layer region of the substrate. The first and second resistance variation sections are of the second conductivity type and have a dopant concentration lower than that of the first and second dopant diffusion regions. The first main electrode is provided on the first dopant diffusion region of the semiconductor substrate and the second main electrode is provided on the second dopant diffusion region of the semiconductor substrate.

The first charge storage section is provided between the first main electrode and control electrode. The second charge storage section is provided between the second main electrode and control electrode.

The first main electrode is in contact with (or adjacent to) the first charge storage section on the semiconductor substrate, and the second main electrode is in contact with (or adjacent to) the second charge storage section on the semiconductor substrate. Thus, the first and second main electrodes can be also used as the electrodes for injecting hot electrons into the first and second charge storage sections, respectively. Therefore, hot electrons are injected into the first and second charge storage sections by the electric field between the semiconductor substrate surface and the first and second main electrodes. In this case, the effective film thickness of the first and second charge storage sections from the semiconductor substrate surface to the first and second main electrodes decreases, as compared with the conventional semiconductor memory. As a result, the injection efficiency of hot electrons increases. When information is written by the injection of hot electrons, a high voltage is unnecessary because the hot electron injection efficiency is increased. Also, the time for writing is reduced, and the electric current for writing is reduced.

According to another aspect of the present invention, there is provided a method for recording information in a nonvolatile semiconductor memory. The above described semiconductor memory is used. It should be assumed that the first conductivity type is a p type and the second conductivity type is an n type. The information recording method includes the step of applying a positive first control voltage to the control electrode. The information recording method also includes the step of applying a positive first voltage to the first main electrode. The first voltage is higher than the first control voltage. The information recording method also includes the step of connecting the second main electrode to a ground potential.

Preferably, the first control voltage is in a range of 3 to 5 V, and the first voltage is in a range of 5 to 10 V.

According to a still another aspect of the present invention, there is provided a method for recording information in a nonvolatile semiconductor memory. The above described semiconductor memory is used. The first conductivity type is an n type and the second conductivity type is a p type. This information recording method includes the step of applying a negative second control voltage to the control electrode, and the step of applying a negative second voltage to the first main electrode. The negative second voltage has an absolute value greater than that of the second control voltage. The information recording method also includes the step of connecting the second main electrode to a ground potential.

According to yet another aspect of the present invention, there is provided a method for manufacturing a nonvolatile semiconductor memory. The manufacturing method includes the step of forming an insulating film on one main surface of a semiconductor substrate. The semiconductor substrate has a first conductivity type. The manufacturing method also includes the step of forming a control electrode on the insulating film. The manufacturing method also includes the step of implanting a dopant into those regions of the semiconductor substrate that sandwich the control electrode, so as to form dopant low-concentration diffusion layers on opposite sides of the control electrode. The implanted dopant has a second conductivity. The manufacturing method also includes the step of successively laminating a first silicon oxide film layer, a silicon nitride film layer, and a second silicon oxide film layer on the semiconductor substrate, the insulating film and the control electrode to form a laminated body. The manufacturing method also includes the step of etching the laminated body to form charge storage sections on the opposite sides of the control electrode. The manufacturing method also includes the step of implanting a dopant of a second conductivity type into those regions of the dopant low-concentration diffusion layer which are separate (distant) from the control electrode, so as to form dopant diffusion regions on both sides of the control electrode. Those portions of the dopant low-concentration diffusion layer which lie between the dopant diffusion regions and a lower face of the control electrode become resistance variation sections. The manufacturing method also includes the step of forming main electrodes on the dopant diffusion regions of the semiconductor substrate such that the charge storage sections are sandwiched between the control electrode and the main electrodes.

According to another aspect of the present invention, there is provided another method for manufacturing a nonvolatile semiconductor memory. This manufacturing method includes the step of forming an insulating film on a semiconductor substrate. The semiconductor substrate has a first conductivity type. The manufacturing method also includes the step of forming a control electrode on the insulating film. The manufacturing method also includes the step of trench etching opposite two areas adjacent to (across) the control electrode of the semiconductor substrate to form two trenches in one main surface of the semiconductor substrate. A protrusion (e.g., a table-shaped step section) is formed between the two trenches. The manufacturing method also includes the step of implanting a dopant of a second conductivity type in two lateral regions of the control gate. Each of the two lateral regions extends from a flat region which is a bottom surface of each trench to a side surface of the step section, to form dopant low-concentration diffusion layers on opposite sides of the control electrode. The manufacturing method also includes the step of successively laminating a first silicon oxide film layer, a silicon nitride film layer, and a second silicon oxide film layer on the semiconductor substrate, insulating film and the control electrode to form a laminated body. The manufacturing method includes the step of etching the laminated body to form charge storage sections on both sides of the control electrode. The manufacturing method also includes the step of forming a dopant diffusion region in each dopant low-concentration diffusion region by implanting a dopant into a portion of the flat region of the semiconductor substrate. The dopant has the second conductivity type. Other portions of the dopant low-concentration diffusion layer between the dopant diffusion regions and a lower face of the control electrode become resistance variation sections. The manufacturing method includes the step of forming main electrodes on the dopant diffusion regions of the semiconductor substrate such that the charge storage sections are sandwiched between the control electrode and main electrodes.

These and other objects, aspects and advantages of the present invention will become apparent to those skilled in the art from the following detailed description and appended claims when read and understood in conjunction with the accompanying drawings.

### BRIEF DESCRIPTION OF THE DRAWINGS

FIG. 1 is a schematic cross-sectional view of a nonvolatile semiconductor memory of the first embodiment according to the present invention;

FIG. 2 is an enlarged schematic view useful to explain how to record information into the nonvolatile semiconductor memory shown in FIG. 1;

FIGS. 3A, 3B, 3C, 3D, 4A, 4B, 5A and 5B are a series of process diagrams for manufacturing the nonvolatile semiconductor memory;

FIG. 6 is a schematic cross-sectional view of the nonvolatile semiconductor memory according to the second embodiment of the present invention; and

FIG. 7 is a schematic cross-sectional view of the conventional nonvolatile semiconductor memory.

### DETAILED DESCRIPTION OF THE INVENTION

Embodiments of the present invention will be described below with reference to the accompanying drawings. In the following description and the drawings, the shape, dimensions, and relative arrangement of structural elements of a semiconductor memory are shown schematically to a degree facilitating the understanding of the embodiments of the present invention. The compositions (materials) of the structural elements and numerical conditions relating thereto which are explicitly mentioned in the embodiments are mere examples, and do not limit to the scope of the present invention. Therefore, the invention is not limited to the described and illustrated embodiments.

### First Embodiment

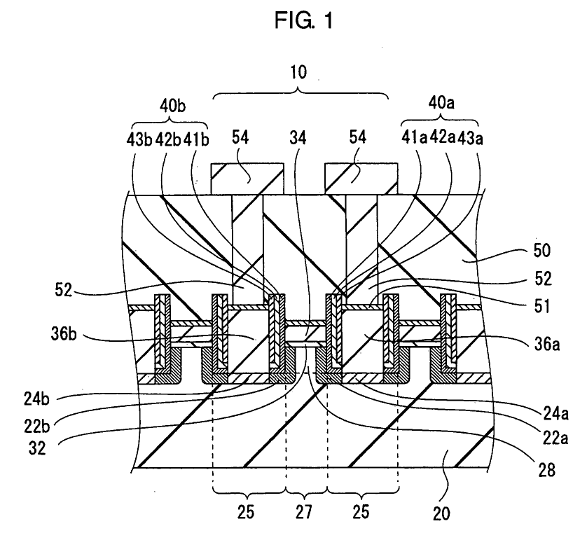

The structure of the nonvolatile semiconductor memory of the first embodiment will be explained below with reference to FIG. 1.

One memory cell 10 of the nonvolatile semiconductor memory includes a p-type silicon substrate 20 as a semiconductor substrate of a first conductivity type, a gate electrode 34 that is a control electrode, first and second dopant diffusion regions 24a and 24b, first and second resistance variation sections 22a and 22b, first and second main electrodes 36a and 36b, and first and second charge storage sections 40a and 40b. Thus, the memory cell 10 includes a MOS-type field effect transistor (MOSFET) having a gate oxide film 32 serving as an insulating film and a gate electrode 34, as well as the first and second charge storage sections 40a and 40b that can store an electric charge.

In the explanation below, the term “dopant diffusion region 24” will represent the first and second dopant diffusion regions 24a and 24b, the term “resistance variation section 22” will represent the first and second resistance variation sections 22a and 22b, the term “main electrode 36” will represent the first and second main electrodes 36a and 36b, and the term “charge storage section 40” will represent the first and second charge storage sections 40a and 40b.

One main surface (upper surface) of the silicon substrate 20 has two types of surfaces having different heights which are measured from the other main surface. Those upper surface regions having a lower height are referred to as flat regions 25, and other upper surface regions higher than the flat regions 25 are referred to as step regions 27. The flat regions 25 and step regions 27 extend in parallel to each other alternately. A table-shaped step section 28 protruding upward from the upper surface of the flat region 25 is formed in each step region 27. The step sections 28 is formed, for example, by performing trench etching from the upper surface of the silicon substrate 20, and trenching some portions of the silicon substrate that correspond to the flat regions 25 to lower those positions of the main surface. If the top of each step section 28 has a rectangular shape, the top of each flat section 25 also will have a rectangular shape. The trenches made by the trench etching define the flat regions.

The gate electrode 34 is formed from polysilicon and provided via the gate oxide film 32 on each step section 28 of the silicon substrate 20.

The first and second dopant diffusion regions 24a and 24b are formed in the flat regions 25 of the silicon substrate 20 in positions sandwiching the gate electrode 34, when viewed from the upper surface side of the silicon substrate 20. The dopant diffusion region 24 is a region of a second conductivity type that is different from the conductivity type of the silicon substrate 20. In this embodiment, the dopant diffusion region 24 is a region (n⁺ region) into which n-type dopants have diffused to a high concentration. The dopant diffusion region 24 functions as a main electrode region, that is a drain or a source, during the MOSFET operation.

The resistance variation section 22 is also formed in the surface layer region of the silicon substrate 20. The first resistance variation section 22a is formed over the entire zone in the channel direction of the MOSFET between the right lower face of the gate electrode 34 and the left side of the first dopant diffusion region 24a. The second resistance variation section 22b is formed over the entire zone in the channel direction of the MOSFET between the left lower face of the gate electrode 34 and the right side of the second dopant diffusion region 24b. When viewed from the upper surface side of the silicon substrate 20, the resistance variation section 22a is located between the gate electrode 34 and dopant diffusion region 24a, and the resistance variation section 22b is located between the gate electrode 34 and dopant diffusion region 24b. Thus, the resistance variation section 22a (22b) extends from the end of the dopant diffusion region 24a (24b) along the upper surface of the flat region 25 and side surface of the step section 28, and ends at the upper surface of the step section 28. A dopant of the same conductivity type as the dopant diffusion region 24 is implanted in the resistance variation section 22. The resistance variation section 22 is a region (n⁻ region) with a dopant concentration lower than that in the dopant diffusion region 24 and generates hot electrons when information is recorded. In FIG. 1, the layer thickness of the resistance variation section 22 is equal to the layer thickness of the dopant diffusion region 24. It should be noted, however, that the layer thickness of the dopant diffusion region 24 may be larger than the layer thickness of the resistance variation section 22.

The first main electrode 36a and second main electrode 36b are formed respectively on the first and second dopant diffusion regions 24a and 24b of the silicon substrate 20.

When viewed from the top of the silicon substrate 20, the first charge storage section 40a is sandwiched between the first main electrode 36a and gate electrode 34. The first charge storage section 40a is formed over the entire zone in the channel direction (right and left direction in FIG. 1) of the MOSFET. The first charge storage section 40a is in direct contact with the first main electrode 36a and gate electrode 34. The first charge storage section 40a has a laminated structure (referred to hereinbelow as an ONO laminated insulating film) in which a first silicon oxide film 41a, a silicon nitride film 42a, and a second silicon oxide film 43a are laminated successively in the channel direction of the MOSFET.

The first silicon oxide film 41a is formed to a thickness of about 5 to 10 nm from above the flat region 25 of the silicon substrate 20 over the side walls of the step section 28, gate oxide film 32 and gate electrode 34. Similar to the first silicon oxide film 41a, the silicon nitride film 42a is formed to a thickness of about 5 to 10 nm on the first silicon oxide film 41a from above the flat region 25 of the silicon substrate 20 over the side walls of the step section 28, gate oxide film 32 and gate electrode 34. The second silicon oxide film 43a is formed to a thickness of about 2 to 10 nm on the silicon nitride film 42a and is in contact with the side wall of the first main electrode 36a.

When viewed from the top of the silicon substrate 20, the second charge storage section 40b is provided over the entire zone in the channel direction of the MOSFET between the second main electrode 36b and gate electrode 34 on the silicon substrate 20. Similar to the first charge storage section 40a, the second charge storage section 40b is an ONO laminated insulating film.

The carriers injected into the charge storage section 40 are accumulated mainly in the silicon nitride film 42 amongst the components of the ONO laminated insulating film. The material and configuration of the charge storage section 40 can be selected freely and advantageously according to the memory application, and a structure can be employed in which at least one insulating film selected from the group of insulating films including a silicon nitride film, an aluminum oxide film, and a hafnium oxide film is sandwiched between the first silicon oxide film 41 and second silicon oxide film 43. The resistance variation section and charge storage section may be also configured so as to be only provided between the gate electrode and first dopant diffusion region or between the gate electrode and second dopant diffusion region. Providing the resistance variation sections and charge storage sections between the gate electrode and first dopant diffusion region and also between the gate electrode and second dopant diffusion region makes it possible to write 2-bit information into one memory cell.

An interlayer insulating film 50 is formed on the gate electrode 34, charge storage section 40, and main electrode 36. A contact plug 52 is provided in the interlayer insulating film 50. The contact plug 52 is also electrically connected to the main electrode 36 via cobalt silicide 51. The contact plug 52 is electrically connected to a metal wiring 54 formed on the interlayer insulating film 50.

In the nonvolatile semiconductor memory of the first embodiment, the flat regions and step regions are provided in the silicon substrate, and the gate oxide film and gate electrode are provided on the table-shaped step section formed in the step region. In such a configuration, the charge storage section is sandwiched between the main electrode and side surface of the step section located below the gate electrode. The resistance variation section is provided on the side surface of the step section. As a result, an electric field is generated to take the shortest distance through the charge storage section between the main electrode and the side surface of the step section, and therefore the maximum electric field is obtained. Because the injection electric field of hot electrons generated in the resistance variation section is increased (enhanced), the injection efficiency of hot electrons can be increased. As a result, it is not necessary to raise a voltage for injecting the hot electrons. Also, the information write time is shortened so that the electric current consumed during writing can be decreased.

In order to maximize the electric field of the charge storage section 40, the height of the step section 28 is preferably equal to or larger than the sum of the thicknesses of the first silicon oxide film 41 and silicon nitride film 42. The reason therefor will be described later. When the thickness of the first silicon oxide film is 5 nm and the thickness of the silicon nitride film is also 5 nm, the height of the step section is preferably 10 nm or more. No specific limitation is placed on the upper limit value of the step section height, but with consideration for the time of etching treatment conducted to form the flat sections, this upper limit value is preferably 50 nm or less.

In general, if the nonvolatile semiconductor memory has an ONO structure, the substantial distance (length) of the resistance variation section in the direction of drain current flow is required to be about 30 to 50 nm to increase the variation of current during reading. For this reason, the charge storage section that is also used as a side wall for forming the dopant diffusion layer is formed with a thickness of about 30 to 50 nm.

In the nonvolatile semiconductor memory of the first embodiment, the resistance variation section extends from the flat region to the side wall of the step section. With such a configuration, the substantial distance of the resistance variation section is increased by the height of the step section. Therefore, the distance of the portion of the resistance variation section that is formed in the flat region can be decreased and the thickness of the charge storage section in the direction of drain current flow can be reduced. As a result, the film thickness of the charge storage section decreases and the electric field for injecting hot electrons can be increased.

In the first embodiment, a p-type silicon substrate is used as the semiconductor substrate of the first conductivity type, but the present invention is not limited in this regard. For example, a p-type well may be provided in the n-type silicon substrate and such substrate may be used as the semiconductor substrate of the first conductivity type. It should be noted that the first conductivity type may be an n type, and the second conductivity type may be a p type.

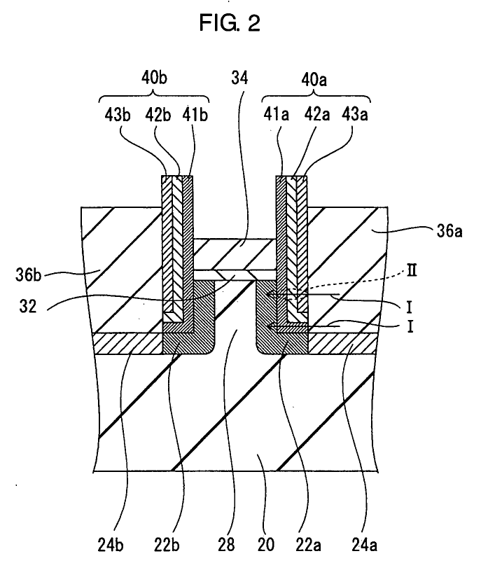

A method for recording information in the nonvolatile semiconductor memory of the first embodiment will be explained below with reference to FIG. 2. The process of recording of information means injecting electric charges (for example, hot electrons) into the charge storage section provided in the nonvolatile semiconductor memory and holding the charge therein.

In the following description, the first dopant diffusion region 24a is taken as a drain, the second dopant diffusion region 24b is taken as a source, the first main electrode 36a is taken as a drain electrode, and the second main electrode 36b is taken as a source electrode.

The electric potential of the silicon substrate 20 and source electrode 36b is set to a ground potential (0 V). A first control voltage within a range of 3 to 5 V that is sufficient for forming carriers is applied as a gate voltage to the gate electrode 34. A first voltage within a range of 5 to 10 V that is higher than the first control voltage is applied as a drain voltage to the drain electrode 36a. This drain voltage has a value sufficient to generate hot electrons in the first resistance variation section 22a. If the drain voltage is higher than the gate voltage, then the electric force lines (as indicated by the arrows I in FIG. 2) that are present between the drain electrode and silicon substrate can be used for pulling the hot electrons into the charge storage section.

If the height of the step section 28 is equal to or larger than the sum of the thicknesses of the first silicon oxide film 41a and silicon nitride film 42a, then the first silicon oxide film 41a, silicon nitride film 42a, and second silicon oxide film 43a can be sandwiched, like parallel flat plates, between the side wall of the step section 28 and the drain electrode 36a (a portion indicated by II in the drawing).

Because the drain voltage is greater than the gate voltage and the memory cell has a configuration in which the charge storage section 40a is sandwiched by the drain electrode 36a and step section 28 of the silicon substrate 20, the electric force lines between the drain electrode 36a and resistance variation section 22a of the silicon substrate 20 pass via the shortest path and the electric field of the charge storage section attains a maximum value.

If the nonvolatile semiconductor memory has a p-type MOSFET (PMOS) using an n-type silicon substrate as a semiconductor substrate of the first conductivity type, a negative second control voltage within a range of from −3 to −5 V may be applied as a gate voltage to the gate electrode 34, and a negative second voltage within a range of from −5 to −10 V that has an absolute value larger than that of the second control voltage may be applied as a drain voltage to the drain electrode 36a.

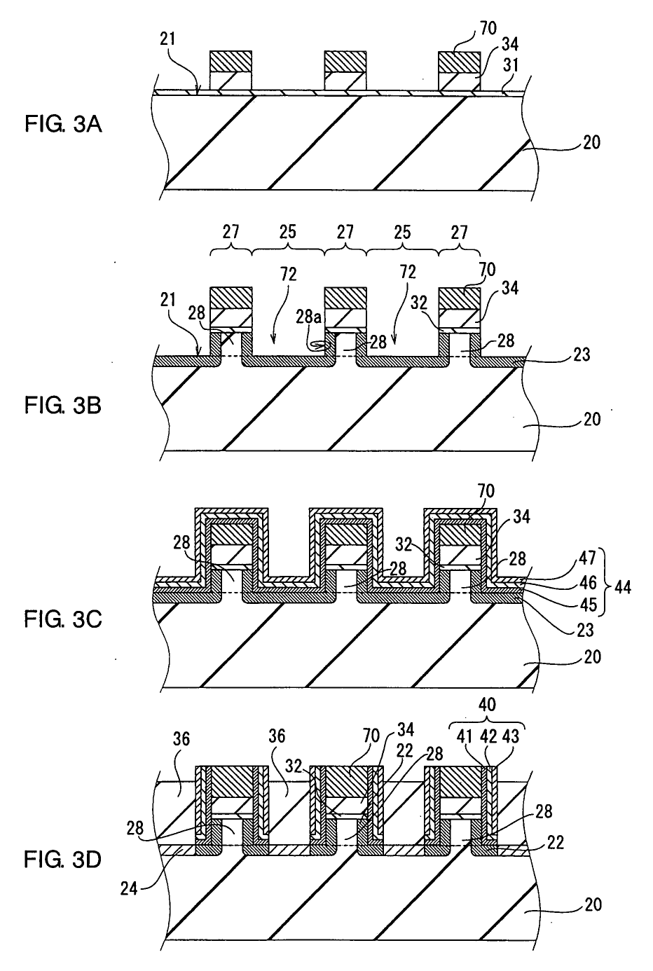

A method for manufacturing the nonvolatile semiconductor memory will be explained below with reference to FIGS. 3A to 3D, FIGS. 4A and 4B, and FIGS. 5A and 5B. FIGS. 3A to 3D, FIGS. 4A and 4B, and FIGS. 5A and 5B are process diagrams of the semiconductor memory manufacturing method and show the cross sectional views of the structures obtained in each step of the manufacturing process.

A method for manufacturing the nonvolatile semiconductor memory of the first embodiment of the present invention includes the first to seventh steps executed sequentially.

In the first step, a p-type silicon substrate is used as a semiconductor substrate of a first conductivity type, a gate oxide film is formed as an insulating film on the silicon substrate, and a gate electrode that serves as a control electrode is formed on the gate oxide film. It should be noted that a silicon substrate including a p-type well in a n-type substrate may be used as the p-type silicon substrate.

In this step, first, a silicon oxide film 31 and a polysilicon layer are successively laminated on one main flat surface 21 of the silicon substrate 20. The formation of the silicon oxide film 31 can be performed, for example, by thermal oxidation, and the formation of the polysilicon layer can be performed, for example, by CVD (Chemical Vapor Deposition). Then, a silicon nitride film is formed, for example, by CVD on the polysilicon layer. Photolithography and dry etching are used to process the silicon nitride film into a silicon nitride film mask 70 that covers regions corresponding to the gate electrodes of the polysilicon layer and exposes other regions. The polysilicon layer is then processed by dry etching using the silicon nitride film mask 70 to form the gate electrodes 34 (FIG. 3A).

A gate oxide film 32 is then formed by processing the silicon oxide film 31 by dry etching using the silicon nitride film mask 70 and gate electrodes 34 as a mask.

In the second step, a plurality of table-shaped step sections 28 are formed on the main surface 21 of the silicon substrate 20.

In this step, trenches (grooves) 72 are formed in the main surface of the silicon substrate 20 by trench etching using the silicon nitride film mask 70 and gate electrodes 34 as a mask. The bottom surface of each trench 72 is a flat surface parallel to the main surface 21. The trenches 72 are formed parallel to each other with a constant width. The etching for forming the trenches 72 can be performed by any advantageous anisotropic dry etching from the perpendicular direction. The regions of the silicon substrate 20 where the trenches 72 are formed are called flat regions 25, and the regions under the gate electrodes 34 where no etching is performed, that is, regions where the table-shaped step sections 28 are formed are called step regions 27. The depth of the trench 72, that is, the height of the step section 28 from the upper surface of the silicon substrate 20 in the flat region 25 is about 10 to 50 nm and preferably the step section 28 is positioned above the position of the silicon nitride film of the ONO laminated insulating film which will be formed in a subsequent step.

In the third step, low-concentration dopant diffusion layers 23 are formed in the regions of the silicon substrate 20 that sandwich each gate electrode 34 from both sides, when viewed from the main surface 21 side of the silicon substrate. The low-concentration dopant diffusion layers 23 extend from the flat regions 25 of the silicon substrate 20 to the side surfaces 28a of each step section 28. The layers 23 have a constant thickness, measured from the surfaces 21 and 28a. In order to form the low-concentration dopant diffusion layer in the side surface 28a of the step section 28, n-type dopants are implanted as the dopants of the second conductivity type from the direction inclined 45 degrees with respect to the upper surface of the substrate. In this embodiment, arsenic (As) is implanted as the dopant to a concentration of about 1×10¹³/cm². The low-concentration dopant diffusion layers 23 extend downward from the top surface of each step section 28 along the side surfaces 28a of the step section 28 that are exposed in the adjacent trenches 72 and also extend along the bottom surfaces of the trenches 72 toward the side surfaces 28a of the neighboring (right and left) step sections 28 (FIG. 3B).

In the fourth step, a first silicon oxide film layer 45, a silicon nitride film layer 46, and a second silicon oxide film layer 47 are successively laminated on the silicon substrate 20 to form a laminated body 44.

In this step, initially, the first silicon oxide film layer 45 is formed by thermal oxidation. The first silicon oxide film layer 45 is formed from above the flat regions 25 of the silicon substrate 20 over the side walls of the step sections 28, the side walls of gate oxide films 32, and the side walls of the gate electrodes 34 and further along the side walls and upper surfaces of the silicon nitride film masks 70. Then, the silicon nitride film layer 46 is formed by CVD on the first silicon oxide film layer 45. Subsequently, the second silicon oxide film layer 47 is formed by CVD on the silicon nitride film layer 46 (FIG. 3C).

In the fifth step, a plurality of charge storage sections 40 are formed by processing the laminated body 44 by anisotropic etching from the orthogonal direction. This etching removes those portions of the laminated body 44 that are formed on the flat sections 25 and formed on the upper surfaces of the silicon nitride film masks 70 on the gate electrodes 34. Thus, the first silicon oxide film 41, silicon nitride film 42, and second silicon oxide film 43 that are formed along the side walls of each step section 28, gate oxide film 32, gate electrode 34, and silicon nitride film mask 70 remain as the charge storage sections 40.

In the sixth step, a plurality of dopant diffusion regions 24 are formed in the silicon substrate 20 of the flat regions 25 that are exposed due to the removal of the portions of the laminated body 44 in the fifth step. As is implanted as an exemplary dopant to about 1×10¹⁵/cm². Due to the As implantation, the dopant diffusion region 24 is formed in each flat region 25 at the low-concentration dopant diffusion layer 23 level. Other portions of the low-concentration dopant diffusion layer 23 where the dopant diffusion regions 24 are not formed become resistance variation sections 22.

In the seventh step, a main electrode 36 is formed on each dopant diffusion region 24 of the silicon substrate 20 (FIG. 3D).

In this process, polysilicon is deposited by CVD so as to be embedded in the region sandwiched by each two charge storage sections 40 on the flat sections. Then, the polysilicon is flattened by CMP (Chemical Mechanical Polishing), and the height of the polysilicon is reduced by dry etching to obtain the main electrode 36. Because the main electrodes 36 will be used as drain electrodes or source electrodes, they have to be made sufficiently low to prevent short circuit with the neighboring gate electrodes 34.

As described hereinabove, the charge storage sections 40 and main electrodes 36 are formed parallel to the gate electrodes 34 over the entire zone in the channel width direction (i.e., a direction perpendicular to the drawing sheet) on the silicon substrate 20.

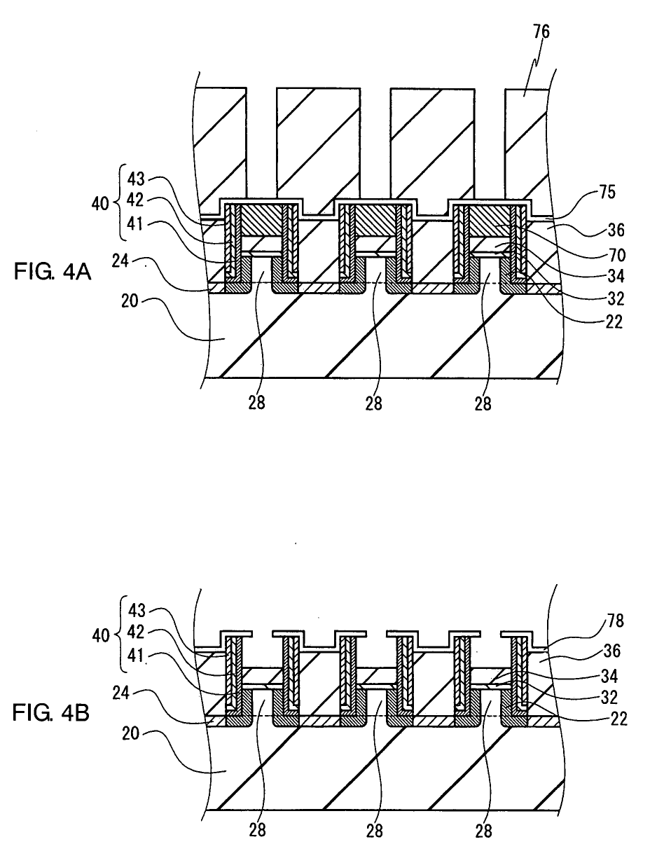

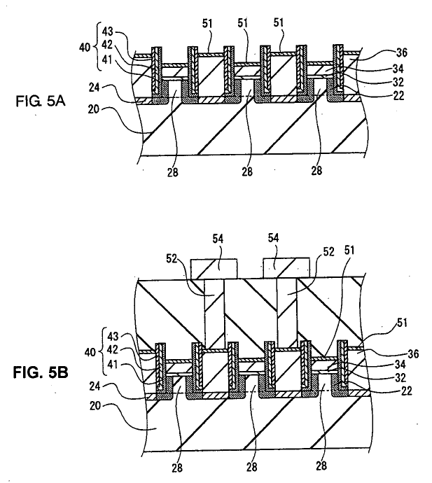

An interlayer insulating film and contacts can be formed by a conventional well-known method after the main electrodes 36 have been formed. These processes will be described with reference to FIGS. 4A, 4B, 5A and 5B.

First, a silicon oxide film 75 is formed by CVD. Then, a resist pattern 76 is formed by photolithography, with portions of the silicon oxide film 75 above the gate electrodes 34 being exposed. The resist pattern 76 covers other portions of the silicon oxide film 75 than above the gate electrodes 34 (FIG. 4A).

The portions of the silicon oxide film 75 located above the gate electrodes 34 are then removed by dry etching using the resist pattern 76, and a silicon oxide film mask 78 is produced.

The resist pattern 76 is then removed by ashing and washing. Wet etching by hot phosphoric acid is then performed by using the silicon oxide film mask 78, and the silicon nitride film masks 70 formed on the gate electrode 34 are removed (FIG. 4B).

The silicon oxide film mask 78 is then removed by dry etching. A Co/TiN laminated film is formed by sputtering on the polysilicon and then heat treatment is performed at a temperature of about 500° C. to form cobalt silicide (CoSix) on the polysilicon. No silicide is formed in the silicon oxide film and silicon nitride film and Co remains therein.

Selective etching is performed by using the conventional APM (a liquid mixture of ammonia, hydrogen peroxide, and water) and SPM (a liquid mixture of sulfuric acid, hydrogen peroxide, and water) and the Co/TiN laminated film is removed from portions other than the cobalt silicide 51 located on the gate electrodes 34 and main electrodes 36 (FIG. 5A).

A silicon oxide film is then deposited by CVD and flattening is performed by a CMP technique to form an interlayer insulating film. Contact holes are then opened by photolithography and dry etching.

W/TiN is deposited into the contact holes by CVD and then flattening is performed by CMP or etch back to obtain contact plugs 52.

Al/TiN is deposited by sputtering on the interlayer insulating film and then a metal wiring 54 is formed by photolithography and dry etching (FIG. 5B).

### Second Embodiment

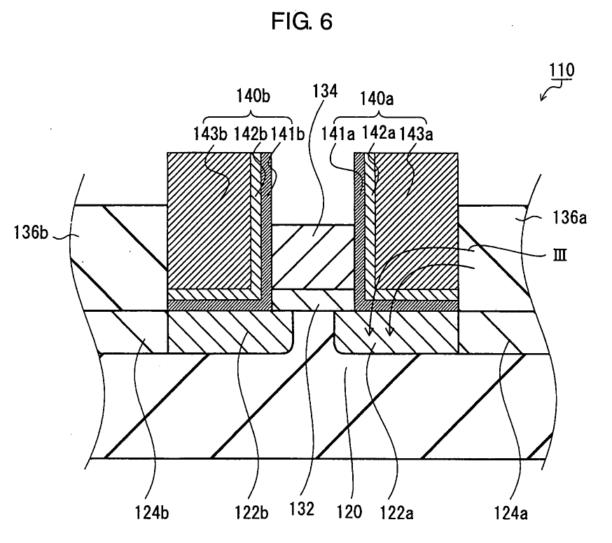

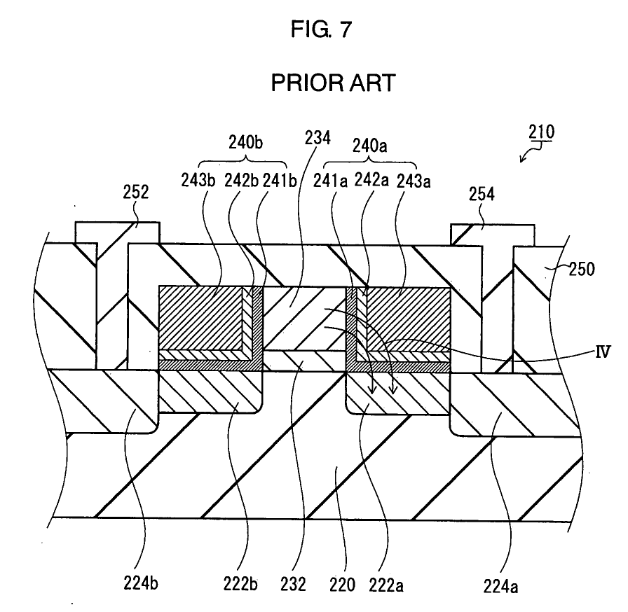

The nonvolatile semiconductor memory of the second embodiment of the present invention will be described below with reference to FIG. 6. FIG. 6 shows a schematic cross sectional view of the nonvolatile semiconductor memory of the second embodiment.

In the nonvolatile semiconductor memory of the first embodiment shown in FIG. 1, the flat regions and step regions including the table-shaped step sections that are higher than the flat regions are formed on one main surface (upper surface) of the silicon substrate 20, and the gate oxide films 32 and gate electrodes 34 are formed on the step sections of the silicon substrate.

By contrast, in the nonvolatile semiconductor memory of the second embodiment, no step section is formed on the upper surface of the silicon substrate; instead, this surface is a flat surface. With the exception of the step sections being absent at the silicon substrate 120, the features and structures of the nonvolatile semiconductor memory of the second embodiment are identical to those of the nonvolatile semiconductor memory of the first embodiment and the redundant explanation will be omitted in the following description.

Referring to FIG. 6, one memory cell 110 of the nonvolatile semiconductor memory has a p-type silicon substrate 120 as a semiconductor substrate of a first conductivity type, a gate electrode 134 serving as a control electrode, first and second dopant diffusion regions 124a, 124b, first and second resistance variation sections 122a and 122b, first and second main electrodes 136a and 136b, and first and second charge storage sections 140a and 140b. Thus, the memory cell 110 has a MOSFET having the gate oxide film 132 serving as an insulating film and a gate electrode 134 and also has a pair of first and second charge storage sections 140a and 140b that can store an electric charge.

The first main electrode 136a and second main electrode 136b, which are made from polysilicon, are formed on the first and second dopant diffusion regions 124a and 124b, respectively, of the silicon substrate 120.

Similar to the first embodiment, the first charge storage section 140a has a laminated structure in which a first silicon oxide film 141a, a silicon nitride film 142a, and a second silicon oxide film 143a are successively laminated and the second charge storage section 140b has a laminated structure in which a first silicon oxide film 141b, a silicon nitride film 142b, and a second silicon oxide film 143b are successively laminated.

A method for recording information in the nonvolatile semiconductor memory of the second embodiment will be described below. In the following description, the first dopant diffusion region 124a is taken as a drain, the second dopant diffusion region 124b is taken as a source, the first main electrode 136a is taken as a drain electrode, and the second main electrode 136b is taken as a source electrode.

The electric potential of the silicon substrate 120 is assumed to be a ground potential (0 V) and the electric potential of the source electrode 136b is also assumed to be the ground potential. A first control voltage within a range of 3 to 5 V that is sufficient to form carriers is applied as a gate voltage to the gate electrode 134. A first voltage within a range of 5 to 10 V that is higher than the first control voltage is applied as a drain voltage to the drain electrode 136a. This drain voltage has a value sufficient to generate hot electrons in the first resistance variation section 122a. If the drain voltage is higher than the gate voltage, then the electric force lines (as indicated by the arrows III in the figure) that are present between the drain electrode and silicon substrate can be used for pulling the hot electrons into the charge storage section.

When hot electrons are injected into the charge storage section of the nonvolatile semiconductor memory of the second embodiment, the drain electrode 136a can be used as an electrode for carrier injection, if the first voltage which is applied to the drain electrode 136a is higher than the first control voltage which is applied to the gate electrode 134. In this case, the kinetic energy of the carriers moving towards the drain 124a can be used for injecting the carriers. Therefore, the carrier injection efficiency is increased.

The nonvolatile semiconductor memory of the second embodiment can be manufactured by a similar method to that of the first embodiment explained with reference to FIGS. 3A to 5B. It should be noted, however, that the nonvolatile semiconductor memory of the second embodiment has no table-shaped step sections 28. In other words, the upper surface of the silicon substrate 120 is flat. Therefore, the third step of the manufacturing method is carried out after the first step, without performing the second step.

In addition, because the silicon substrate 120 has no step sections 28, the implantation of dopants in the third step is performed from the orthogonal direction.

All the steps other than the second and third step are identical to those of the first embodiment and the explanation thereof is omitted.

This application is based on Japanese Patent Application No. 2006-142476 filed on May 23, 2006 and the entire disclosure thereof is incorporated herein by reference.

What is claimed is:

1. A nonvolatile semiconductor memory comprising:
a semiconductor substrate of a first conductivity type;
an insulating film provided on a first main surface of said semiconductor substrate;
a control electrode provided on the insulating film;
first and second dopant diffusion regions of a second conductivity type different from said first conductivity type, the first and second dopant diffusion regions being provided in a surface layer of the first main surface of said semiconductor substrate at positions sandwiching said control electrode;
first and second resistance variation sections of the second conductivity type, each of the first and second resistance variation sections having a dopant concentration lower than a dopant concentration of said first dopant diffusion region, the first and second resistance variation sections being formed in the surface layer of the first main surface of said semiconductor substrate, the first resistance variation section extending to a lower surface of the control electrode from the first dopant diffusion region and the second resistance variation section extending to the lower surface of the control electrode from the second dopant diffusion region;
a first main electrode provided on said first dopant diffusion region of said semiconductor substrate;
a second main electrode provided on said second dopant diffusion region of said semiconductor substrate;
a first charge storage section provided between said first main electrode and said control electrode; and
a second charge storage section provided between said second main electrode and said control electrode.

2. The nonvolatile semiconductor memory according to claim 1, wherein said semiconductor substrate has first and second flat regions and a step region located between said first and second flat regions, said step region has an upper surface higher than said flat regions, and said step region has a first side surface and a second side surface;
said insulating film is provided on said step region of said semiconductor substrate;
said first dopant diffusion region is formed in said first flat region of the surface layer of the semiconductor substrate, and said second dopant diffusion region is formed in said second flat region of the surface layer of the semiconductor substrate; and
said first resistance variation region extends along the first side surface of the step region and said second resistance variation region extends along the second side surface of the step region.

3. The nonvolatile semiconductor memory according to claim 2, wherein each of said first and second charge storage sections has a laminated layer structure made from a first silicon oxide film, a silicon nitride film, and a second silicon oxide film.

4. The nonvolatile semiconductor memory according to claim 3, wherein a height of said step section is larger than a sum of a thickness of said first silicon oxide film and a thickness of said silicon nitride film.

5. The nonvolatile semiconductor memory according to claim 1, wherein the first conductivity type is a p-type or an n-type, the control electrode is a gate electrode, the first main electrode is one of drain and source electrodes, and the second main electrode is the other of the drain and source electrodes.

6. The nonvolatile semiconductor memory according to claim 3, wherein a thickness of said first silicon oxide film is about 5 to 10 nm, a thickness of said silicon nitride film is about 5 to 10 nm, and a thickness of said second silicon oxide film is about 2 to 10 nm.

7. The nonvolatile semiconductor memory according to claim 2, wherein each of said first and second charge storage sections has a laminated layer structure made from a first silicon oxide film, a second insulating film, and a second silicon oxide film.

8. The nonvolatile semiconductor memory according to claim 7, wherein said second insulating film includes at least one of a silicon nitride film, an aluminum oxide film and a hafnium oxide film.
